(19) United States
(12) Patent Application Publication
(10) Pub. No.: US 2005/0255411 A1
(43) Pub. Date: Nov. 17, 2005

(54) Multiple exposure and shrink to achieve reduced dimensions

(76) Inventors: Rex Frost, Hillsboro, OR (US); Swaminathan Sivakumar, Protland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/846,616

(22) Filed: May 14, 2004

(51) Int. Cl. G03F 7/00

(52) U.S. Cl. 430/312; 430/394; 430/330

(57) ABSTRACT

The embodiments of the present invention include decomposing a pattern into dependent patterns. The dependent patterns may then be transferred to a semiconductor wafer surface and the pattern's features may be shrunk. The shrunk features may be transferred to the substrate. The multiple exposures and shrinks facilitate smaller feature dimensions.

### TECHNICAL FIELD

The invention relates to methods and apparatus for processing semiconductor wafers. In particular, the present invention relates to photolithographic methods and apparatus for processing semiconductor wafers.

### BACKGROUND

In semiconductor wafer processing, patterned elements may be formed on the surface of a semiconductor wafer. Typically, these patterned elements may be formed by photolithography. Photolithography may involve depositing a photoresist material on the semiconductor wafer and selectively exposing the photoresist material to light. Portions of the photoresist exposed to light may react to light and subsequent development so patterned elements may be formed. Semiconductor processing may then transfer the patterned elements to the substrate. Integrated circuits may then be formed using numerous steps of photolithography and other semiconductor processing steps. Manufacture of smaller integrated circuits may generally improve the performance and cost of such devices. The ability to achieve smaller dimensions of patterned elements may be generally understood to be limited more by photolithography than any other semiconductor processing step. Achieving smaller dimensions of patterned elements through photolithography may have numerous difficulties.

### BRIEF DESCRIPTION OF THE DRAWINGS

The invention is illustrated by way of example and not by way of limitation in the figures of the accompanying drawings, in which the like references indicate similar elements and in which:

FIG. 1 illustrates a top-down type view of an apparatus in accordance with one embodiment of the present invention.

FIGS. 2a-2d illustrate cross sectional type views of a method in accordance with one embodiment of the present invention.

FIGS. 3a-3h illustrate cross sectional type views of a method in accordance with one embodiment of the present invention.

FIG. 4 illustrates an operational flow of a method of dual exposure and shrink in accordance with an embodiment of the present invention.

FIG. 5 illustrates an operational flow of a method of dual exposure and shrink, including transfer to the substrate, in accordance with an embodiment of the present invention.

### DETAILED DESCRIPTION

In various embodiments, an apparatus and method relating to transferring a pattern to a semiconductor wafer are described. In the following description, various embodiments will be described. However, one skilled in the relevant art will recognize that the various embodiments may be practiced without one or more of the specific details, or with other methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments.

Various operations will be described as multiple discrete operations in turn, in a manner that is most helpful in understanding the invention. However, the order of description should not be construed as to imply that these operations are necessarily order dependent. In particular, these operations need not be performed in the order of presentation.

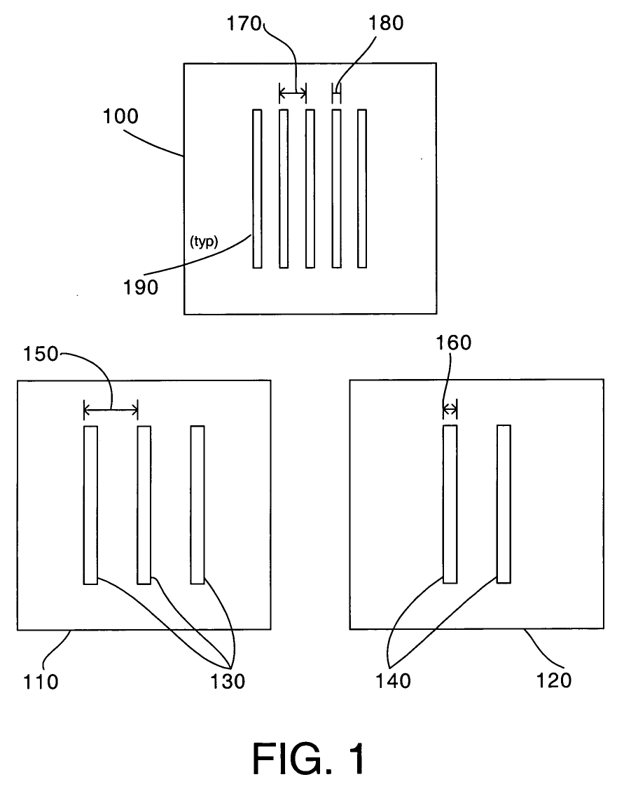

FIG. 1 illustrates a top-down view of a master pattern 100 in accordance with one embodiment of the present invention. The master pattern 100 may be a pattern for layers of integrated circuits desired to be transferred to a semiconductor wafer by photolithography. A process to transfer features from a single pattern to a surface, such as the surface of a semiconductor wafer, may have minimum allowable feature dimensions; the physical limitations of the process prevent features smaller than the minimum allowable feature dimensions from being transferred from the single pattern to the surface. However, the desired pattern on the master pattern may include smaller feature sizes than those allowed by the physical limits for minimum allowable feature dimensions. A method to transfer from a desired pattern feature dimensions smaller than the minimum allowable feature dimensions available using standard transferring methods such as photolithography is discussed herein.

A process to transfer features from a single pattern to a surface may be characterized by a process window. A process window may be defined generally as the furthest deviation from optimal processing conditions where the desired pattern may still be successfully transferred to the semiconductor wafer. The process window may depend largely on the photolithography process chosen and the feature dimensions in the pattern being transferred. Generally, more advanced and costly photolithography processes may allow for larger process windows at the same feature size in the desired pattern. For smaller feature dimensions, certain photolithography processes may have no associated process window because the process, even at optimal conditions, cannot achieve the feature dimensions. For those patterns, a more advanced photolithography process may need to be chosen. Generally, minimum allowable feature dimensions will be associated with a very small process window in the most advanced photolithography process.

A pattern with larger feature dimensions may have an associated larger process window (using the same photolithography process) than a pattern with smaller feature dimensions. A larger process window may allow for less difficulty in transferring the pattern to the semiconductor surface. Alternatively, larger dimensions may allow a less costly photolithography process to be used. A method to transfer a desired pattern allowing increased photolithography process window or less costly photolithography process is discussed herein.

Referring to FIG. 1, the master pattern 100 includes features 190 and feature dimensions 170, 180. The feature dimension 170 may be a pitch dimension and feature dimension 180 may be a width dimension. Generally, pitch dimensions may be defined as the distance between the same structural elements on like features and width dimensions may be defined as the distance across a feature on a pattern.

The master pattern 100 may be decomposed into a first pattern 110 and a second pattern 120. The first pattern 110 may include a first plurality of features 130 and the second pattern 120 may include a second plurality of features 140. Both the first pattern 110 and the second pattern 120 may include features 130, 140 to be transferred that are as small as the minimum allowable feature dimensions 150, 160. The minimum allowable feature dimensions 150, 160 may be based on the physical limitations of the method used for pattern transfer. In the manufacture of integrated circuits, the method used for pattern transfer may be a photolithography process. Other methods may be used. In a photolithography process, the minimum allowable feature dimensions, may be defined by the resolution of the photolithography process. The resolution of the photolithography process may be influenced by the wavelength of light, optical characteristics of a projection system, photoresist thickness, and many other variables.

In methods described below, the master pattern 100 may have feature dimensions 170, 180 less than minimum allowable feature dimensions 150, 160 of the pattern transfer method used. For example, if a standard 193 nm photolithography process may transfer a feature pitch of a minimum of 150 nm and a feature width of a minimum of 75 nm, the present method may be capable of providing a feature dimension 170 of 75 nm and a feature dimension 180 of 25 nm. In one embodiment of the present invention, the feature dimension 180 is thus smaller than the minimum allowable feature dimension 160 of the process used to transfer features from a single pattern to a surface. In another embodiment, the feature dimension 170 is smaller than the minimum allowable feature dimension 150. In yet another embodiment, the feature dimension 170 may be approximately half the minimum allowable feature dimension 160. Other combinations of feature dimensions 170, 180 may be available.

The master pattern 100 in this example may be decomposed into a first pattern 110 and a second pattern 120. In this example, a standard 193 nm photolithography process may be capable of providing a feature pitch of 150 nm and a feature width of 75 nm when transferring from a single pattern to a surface. The master pattern 100 may include a feature dimension 170 of 75 nm and a feature dimension 180 of 25 nm that may be unallowable based on the chosen transfer method. The first pattern 110 and the second pattern 120 may include a feature dimension 150 of 150 nm, a feature dimension 160 of 75 nm, and may combine to form the master pattern 100 by methods described herein. Transfer of the first pattern 110 and the second pattern 120 may then be allowable based on a standard 193 nm photolithography process. Thus, the feature dimensions of the master pattern 100, which are smaller than the minimum allowable feature dimensions, may be transferred to the surface.

Referring to FIG. 1, the first plurality of features 130 and second plurality of features 140 may be larger than the features 190 and may have an accordingly larger photolithography process window. In one embodiment of the present invention, the increased process window may allow for less difficulty in photolithography processing. In another embodiment, the larger feature sizes may allow for a less costly photolithography process to achieve the master pattern 100. Although not illustrated in FIG. 1, the increase in size of the first plurality of features 130 and second plurality of features 140 from the features 190 may cause those features to overlap if the first pattern 110 and the second pattern 120 were overlaid.

For simplicity, FIG. 1 and subsequent figures illustrate line and space features and, more specifically, nested line and space features. In other embodiments, the features may be isolated line features, isolated space features, isolated or nested hole features, or others. Further, the figures illustrate a master pattern that is decomposed into two dependent patterns, however, more than two dependent patterns may be used. For example, if the master pattern were decomposed into three dependent patterns each capable of being transferred with a 150 nm pitch and 75 nm width, the master pattern may include features with a 50 nm pitch and 10 nm width. As the master pattern is decomposed into more numerous dependent patterns, smaller feature dimensions, particularly feature pitches may be available.

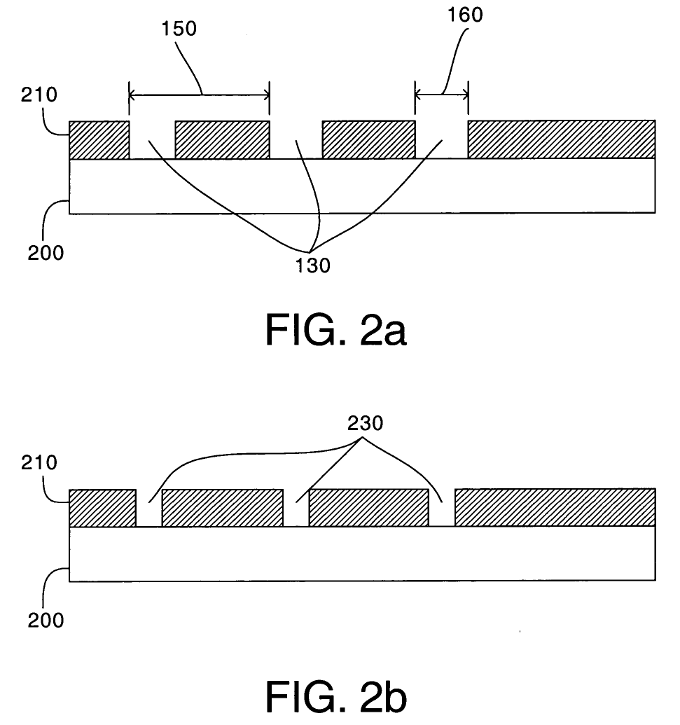

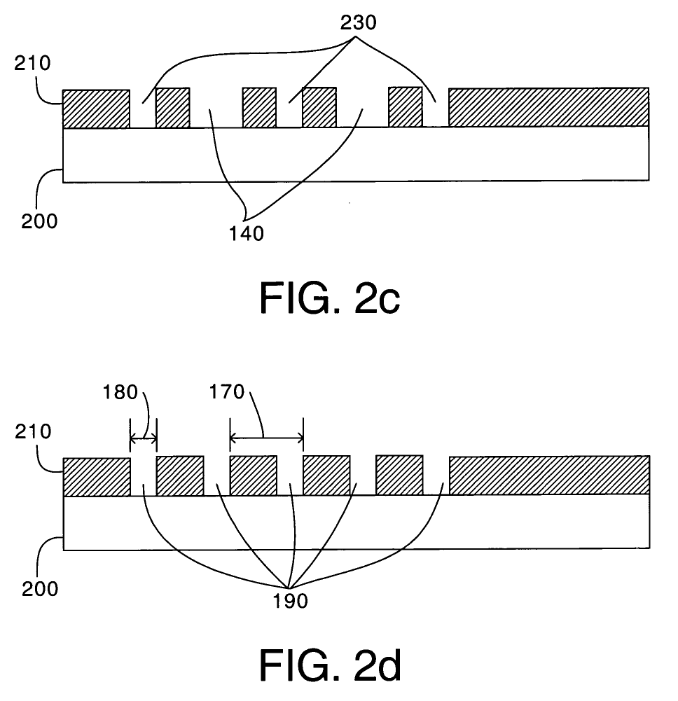

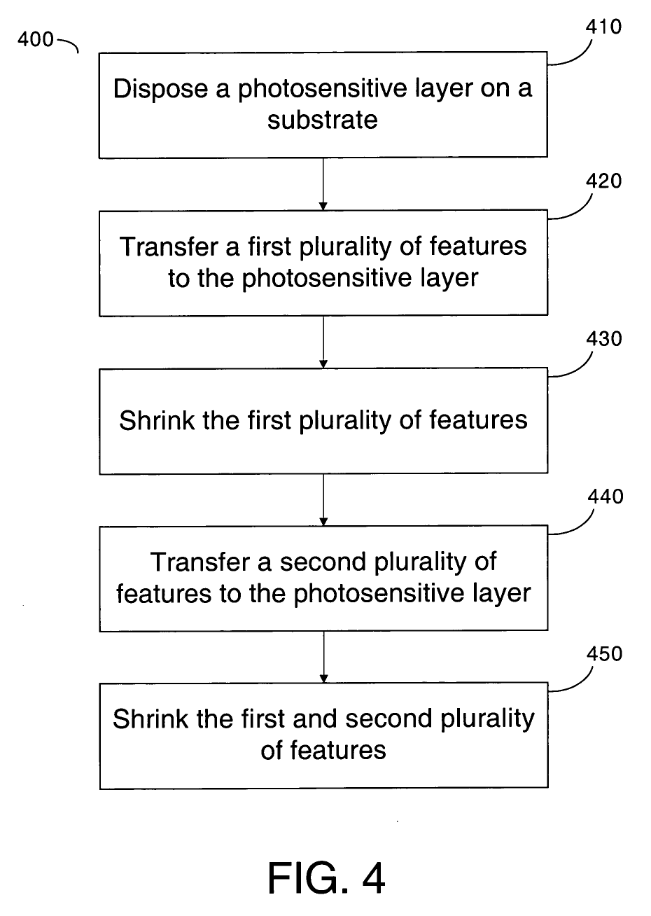

FIGS. 2a-2d illustrate cross sectional type views of a method in accordance with one embodiment of the present invention. FIG. 4 illustrates an operational flow 400 in accordance with an embodiment of the present invention illustrated in FIGS. 2a-2d. While reference is made to the operational flow for clarity, the operational flow is not meant to be limiting. Steps may be added, taken away, or performed out of order without deviating from the spirit of the present invention.

In FIG. 4, box 410 illustrates disposing a photosensitive layer on a substrate. The photosensitive layer may be disposed using a spin on technique or other methods. Box 420 illustrates transferring a first plurality of features to the photosensitive layer. Now referencing FIG. 2a, a first plurality of features 130 may have been transferred to a photosensitive layer 210. In one embodiment, the first plurality of features 130 may have been transferred using photolithography. In other embodiments, the first plurality of features 130 may have been transferred using a 248 nm, 193 nm, 157 nm, or extreme ultra-violet (EUV) photolithography. Other methods may be used. For clarity, pattern transfers will hereinafter be referenced generally as photolithography, but other methods may be used. The photosensitive layer 210 may comprise a positive or negative photoresist or other materials. The substrate 200 may comprise any suitable material. Specific examples may include silicon, germanium, gallium arsenide and silicon on insulator. FIG. 2a also illustrates minimum allowable feature dimensions 150, 160. The minimum allowable feature dimensions 150, 160 may be defined by the photolithography used to pattern the photosensitive layer and may be at the limit of the photolithography process used.

In FIG. 4, box 430 illustrates shrinking the plurality of first features 130 as illustrated in cross sectional view in FIG. 2b. In FIG. 2b, the first plurality of features 130 may have gone through a shrink to form a shrunk first plurality of features 230. In one embodiment, the shrink method may have been a thermal shrink. In a thermal shrink, heat may be applied to the photosensitive layer 210 to reflow it and cause a shrink that forms a shrunk first plurality of features 230. In another embodiment, the shrink method may be a pattern-coating shrink. A pattern-coating shrink may require coating the photosensitive layer 210 with a skin layer and subsequent thermal steps to form a shrunk first plurality of features 230. In yet another embodiment, the first plurality of features 130 may have gone through a self-deactivating shrink to form a shrunk first plurality of features 230. In a self-deactivating shrink, the shrunk first plurality of features 230 may not shrink during subsequent shrink methods. For simplicity of illustration, FIG. 2b does not show additional materials that may be required in some embodiments of the present invention. For simplicity, the term shrink hereinafter generally refers to all available shrink methods.

In FIG. 4, box 440 illustrates transferring a second plurality of features 140 to the photosensitive layer 210 as illustrated in cross sectional view in FIG. 2c. In FIG. 2c, a second plurality of features 140 may have been transferred to the photosensitive layer 210 by photolithography. In one embodiment, the method for transferring the second plurality of features 140 may be the same as the method used for transferring the first plurality of features 130. In other embodiments, a different method may be used. For ease of illustration, an embodiment of the present has been illustrated where the second plurality of features 140 may be substantially centered with respect to the first plurality of features 130. In other embodiments, the second plurality of features may not be centered with respect to the first plurality of features.

In FIG. 2d, the second plurality of features 140 may have gone through a shrink process, as illustrated in box 450 in FIG. 4. Together with the shrunk plurality of first features 230, these features may make up the features 190 of master pattern 100. As illustrated in FIG. 2d, the shrunk plurality of first features 230 may not shrink for a second time when the second plurality of features 140 go through a shrink process. For simplicity of illustration, the features 190 are the same size and feature dimensions 170, 180 are shown as typical. In another embodiment, the shrunk plurality of first features 230 may shrink when the second plurality of features 140 go through a shrink process to form a smaller feature dimension. In yet another embodiment, the first plurality of features 130 may have feature dimensions larger than those of the second plurality of features 140 such that after being shrunk twice, the first plurality of features 130 may be of similar dimension to the second plurality of features 140 being shrunk once. The combination illustrated was chosen for simplicity and clarity and is not meant to be limiting. Other combinations and methods may be available to produce desired results in the master pattern 100.

The feature dimensions 170, 180 illustrated in FIG. 2d may be smaller than those available using standard transferring methods as represented by minimum allowable feature dimensions 150, 160 illustrated in FIG. 2a. As discussed in reference to FIG. 1, many combinations of feature dimensions 170, 180 smaller than the minimum allowable feature dimensions 150, 160 may be available.

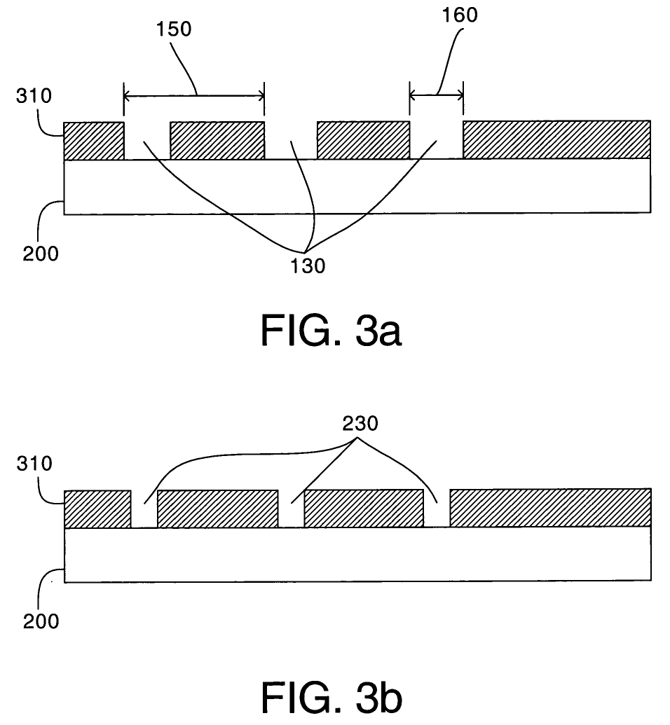

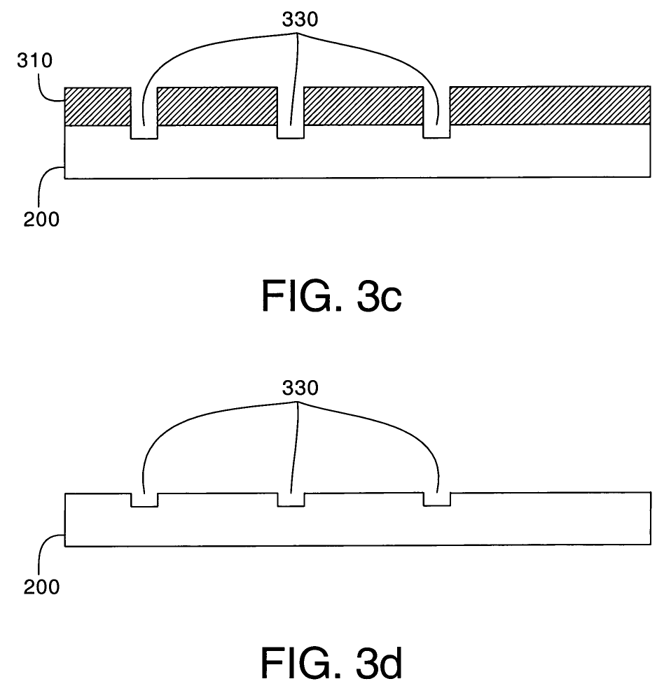

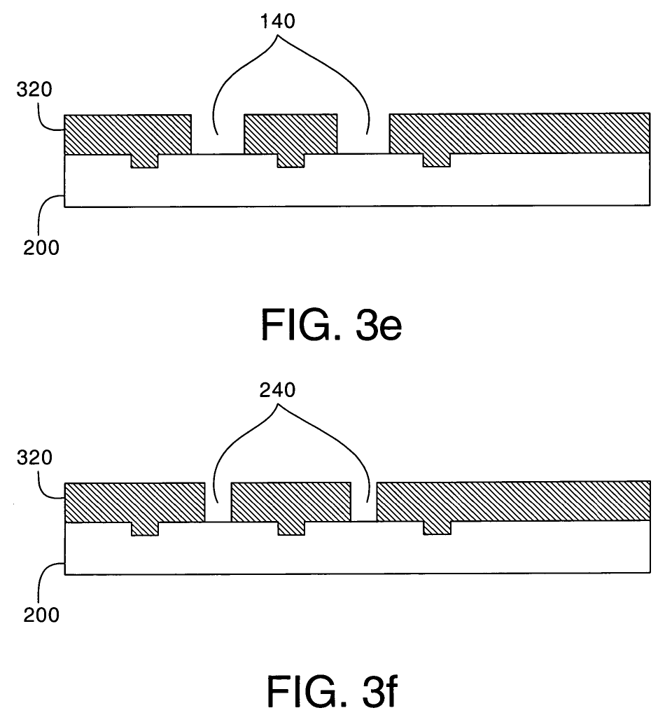

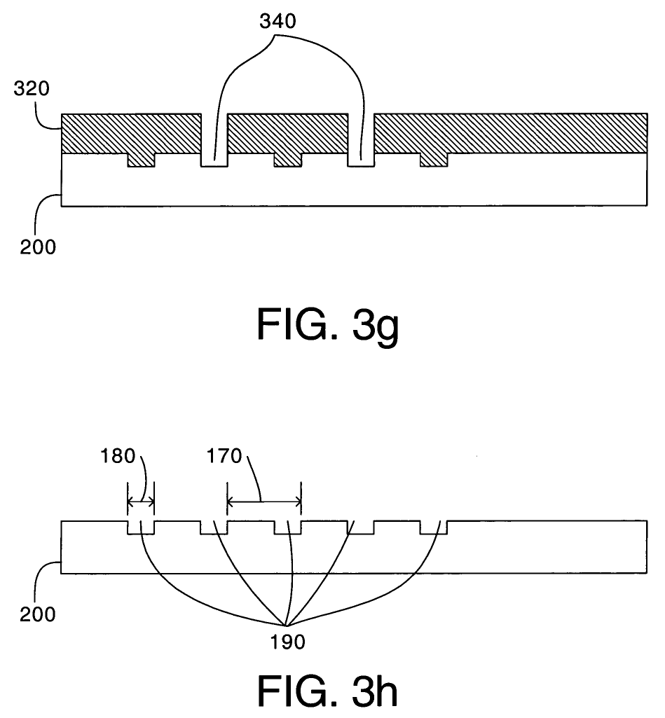

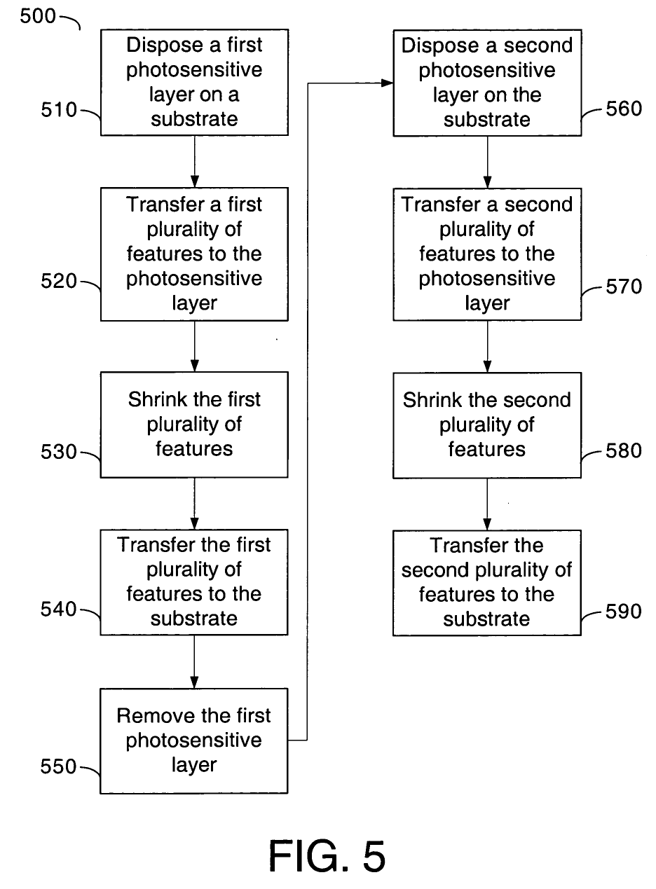

FIG. 5 illustrates an operational flow 500 in accordance with an embodiment of the present invention illustrated in cross sectional views in FIGS. 3a-3h. While reference is made to the operational flow for clarity in the following description, the operational flow is not meant to be limiting. Steps may be added, taken away, or performed out of order without deviating from the spirit of the present invention.

In FIG. 5, box 510 illustrates disposing a first photosensitive layer 310 on a substrate 200. Box 520 illustrates transferring a first plurality of features 130 to the first photosensitive layer 310 as illustrated in cross sectional view in FIG. 3a. In FIG. 3a, a first plurality of features 130 may have been transferred to a first photosensitive layer 310 using photolithography. The first photosensitive layer 310 may comprise a positive or negative photoresist or other materials. As illustrated in FIG. 3b, the first plurality of features 130 may have gone through a shrink process to form a shrunk first plurality of features 230, in analogy to FIG. 2b. Correspondingly, in FIG. 5, box 530 illustrates shrinking the first plurality of features.

As illustrated in FIG. 5, box 540, the shrunk first plurality of features 230 may be transferred to the substrate. Correspondingly, in reference to FIG. 3c, the shrunk first plurality of features 230 may have been transferred to the substrate 200 to form a transferred first plurality of features 330. The transferred first plurality of features 330 may have been transferred using chemical or plasma etch or other methods. In other embodiments, the transferred plurality of features 330 may be transferred onto the substrate 200 (not shown). In such embodiments, the shrunk plurality of features 230 may be filled with a material in a variety of methods including chemical vapor deposition, sputter deposition, and others. The semiconductor surface may then be leveled using a planar semiconductor process. Hereinafter, methods of transferring the shrunk first plurality of features to form a transferred plurality of features 330 will be referenced generally as a transfer, but a variety of methods may be used. As illustrated in FIG. 3d and box 550 of FIG. 5, the first photosensitive layer 310 may be removed from the substrate 200.

Now in reference to FIG. 5, box 560 illustrates a second photosensitive layer 320 may be disposed on the substrate 200. The second photosensitive layer 320 may be positive or negative photoresist or other material. In one embodiment the first photosensitive layer 310 and the second photosensitive layer 320 may be the same material. In other embodiments, they may be different.

Box 570 illustrates a second plurality of features 140 may be transferred to the second photosensitive layer 320. FIG. 3e illustrates a second plurality of features 140 may be transferred to a second photosensitive layer 320 using photolithography. The illustrated embodiment shows the plurality of second features 140 may be substantially centered with respect to the transferred plurality of second features 330. In other embodiments, the second plurality of features 140 may not be centered with respect to the transferred plurality of second features 330.

FIG. 5, box 580 and FIG. 3f illustrate the second plurality of features 140 going through a shrink to form a shrunk second plurality of features 240. In one embodiment of the present invention, the shrink illustrated in box 580 and FIG. 3f may not be performed. For simplicity of illustration in FIG. 3f, an embodiment of the present invention has been shown where the shrunk second plurality of features 240 may have been shrunk to a size similar to the shrunk plurality of first features 230. In another embodiment of the present invention, the shrunk plurality of second features 240 may be shrunk to a different size.

In FIG. 3g, the shrunk plurality of shrunk features 240 may have been transferred to the substrate to form a transferred second plurality of features 340. FIG. 5, box 590 illustrates a similar transfer.

As illustrated in FIG. 3h, the photosensitive material 320 may be removed. Together, the transferred first plurality of features 330 and transferred second plurality of features 340 may form features 190 from master pattern 110. For simplicity of illustration, the features 190 are the same size and feature dimensions 170, 180 are shown as typical. As discussed in other embodiments, the features 190 and their corresponding pitches and widths may be of different feature dimensions 170, 180 to create the desired master pattern 100.

The feature dimensions 170, 180 illustrated in FIG. 3h may be smaller than those available using standard transferring methods as represented by minimum allowable feature dimensions 150, 160 illustrated in FIG. 3a. As discussed in reference to FIG. 1, many combinations of feature dimensions 170, 180 smaller than the minimum allowable feature dimensions 150, 160 may be available.

It is to be understood that the above description is intended to be illustrative, and not restrictive. Many other embodiments will be apparent to those of ordinary skill in the art upon reviewing the above description. The scope of the invention should, therefore, be determined with reference to the appended claims, along with the full scope of equivalents to which such claims are entitled.

1. A method comprising:
disposing a photosensitive layer on a substrate;
transferring a first pattern comprising a first plurality of features to the photosensitive layer;
shrinking the first plurality of features;
transferring a second pattern comprising a second plurality of features to the photosensitive layer; and
shrinking at least one of the first plurality of features or the second plurality of features to form a master pattern.

2. The method of claim 1, wherein at least one of transferring the first pattern or transferring the second pattern is performed by a photolithography process capable of transferring a feature no smaller than a minimum allowable feature dimension.

3. The method of claim 2, wherein the master pattern comprises a feature dimension less than the minimum allowable feature dimension.

4. The method of claim 3, wherein the feature dimension is a pitch.

5. The method of claim 4, wherein the feature dimension is a pitch about in the range of 40% to 60% of the minimum allowable feature dimension.

6. The method of claim 3, wherein the feature dimension is a width.

7. The method of claim 1, wherein the substrate comprises at least one of silicon, germanium, gallium arsenide, or silicon on insulator.

8. The method of claim 1, wherein the photosensitive layer comprises at least one of positive photoresist or negative photoresist.

9. The method of claim 2, wherein the photolithography process comprises at least one of 248 nm photolithography, 193 nm photolithography, 157 photolithography, or EUV photolithography.

10. The method of claim 1, wherein shrinking the first plurality of features comprises at least one of a thermal shrink, a pattern coating shrink, or a self-deactivating shrink.

11. The method of claim 1 further comprising:
transferring the first pattern to the substrate.

12. The method of claim 11, wherein transferring the first pattern to the substrate comprises etching the substrate or deposition onto the substrate.

13. The method of claim 1, wherein at least one of transferring the first pattern or transferring the second pattern is performed by a photolithography process incapable of transferring the master pattern.

14. The method of claim 1, wherein at least one of the first plurality of features and at least one of the second plurality of features would overlap without shrinking the first plurality of features.

15. The method of claim 1, wherein at least one of transferring the first pattern or transferring the second pattern is performed by a photolithography process with a larger process window than available in transferring the master pattern.

16. A method comprising:
disposing a first photosensitive layer on a substrate;
transferring a first pattern comprising a first plurality of features to the photosensitive layer;
shrinking the first plurality of features;
transferring the first plurality of features to the substrate;
removing the first photosensitive layer;
disposing a second photosensitive layer on the substrate; and
transferring a second pattern comprising a second plurality of features to the photosensitive layer to form a master pattern.

17. The method of claim 16 further comprising:
shrinking the second plurality of features.

18. The method of claim 17, wherein shrinking the second plurality of features comprises at least one of a thermal shrink, a pattern coating shrink, or a self-deactivating shrink.

19. The method of claim 16, wherein at least one of transferring the first pattern or transferring the second pattern is performed by a photolithography process capable of transferring a feature no smaller than a minimum allowable feature dimension.

20. The method of claim 19, wherein the master pattern comprises a feature with a feature dimension less than the minimum allowable feature dimension.

21. The method of claim 20, wherein the feature dimension is a pitch.

22. The method of claim 21, wherein the feature dimension is a pitch about in the range of 40% to 60% of the minimum allowable feature dimension.

23. The method of claim 20, wherein the feature dimension is a width.

24. The method of claim 16, wherein the substrate comprises at least one of silicon, germanium, gallium arsenide, or silicon on insulator.

25. The method of claim 19, wherein the photolithography process comprises at least one of 248 nm photolithography, 193 nm photolithography, 157 photolithography, or EUV photolithography.

26. The method of claim 16, wherein transferring the first plurality of features to the substrate comprises at least one of etching the substrate or deposition onto the substrate.

27. The method of claim 16, wherein shrinking the first plurality of features comprises at least one of a thermal shrink, a pattern coating shrink, or a self-deactivating shrink.

28. The method of claim 16, wherein at least one of transferring the first pattern or transferring the second pattern is performed by a photolithography process incapable of transferring the master pattern.

29. The method of claim 16, wherein at least one of the first plurality of features and at least one of the second plurality of features would overlap without shrinking the first plurality of features.

30. The method of claim 16, wherein at least one of transferring the first pattern or transferring the second pattern is performed by a photolithography process with a larger process window than available in transferring the master pattern.

31. A method comprising:
transferring each of at least two dependent patterns, each comprising features, to a photosensitive surface using an imaging system and shrinking at least one of the features, wherein the dependent patterns define a master pattern, and the master pattern has a feature dimension smaller than a minimum allowable feature dimension.

32. The method of claim 31, wherein the minimum allowable feature dimension comprises a resolution limit of the imaging system.

33. The method of claim 31, wherein the feature dimension comprises a feature pitch less the minimum allowable feature dimension.

34. The method of claim 33, wherein the feature pitch is about in the range of 40% to 60% of the minimum allowable feature dimension.

35. The method of claim 31, wherein the imaging system comprises a photolithography imaging system.

36. The method of claim 35, wherein the photolithography imaging system comprises at least one of a 248 nm photolithography imaging system, a 193 nm photolithography imaging system, a 157 nm photolithography imaging system, or an EUV photolithography imaging system.

37. The method of claim 31, further comprising:
disposing the photosensitive surface on a substrate; and
transferring the features to the substrate.

38. A microelectronic die comprising:
a plurality of features, comprising at least one feature pitch and at least one feature width, wherein the feature pitch and width are less than a minimum feature pitch and width allowed by a minimum resolution of a photolithography process used to form the features.

39. The apparatus of claim 38, wherein the plurality of features were formed by disposing a photosensitive material on a substrate, transferring a first plurality of features to the photosensitive material, shrinking the first plurality of features, transferring a second plurality of features to the photosensitive material, and shrinking at least one of the first plurality of features or the second plurality of features.

40. The apparatus of claim 38, wherein the plurality of features were formed by transferring each of at least two dependent patterns, each comprising features, to a photosensitive surface using an imaging system and shrinking at least one of the features, wherein the dependent patterns define a master pattern, and the master pattern has a feature dimension smaller than a minimum allowable feature dimension.
